(19) United States
(12) Patent Application Publication
(10) Pub. No.: US 2025/0294732 A1
(43) Pub. Date: Sep. 18, 2025

(54) MEMORY DEVICE AND MANUFACTURING METHOD THEREOF

(71) Applicant: TAIWAN SEMICONDUCTOR MANUFACTURING COMPANY LTD., HSINCHU (TW)

(72) Inventors: BO-WEI WU, NEW TAIPEI CITY (TW); PO-HSUN CHU, TAINAN CITY (TW); JUNG-HSUAN CHEN, HSINCHU CITY (TW); ZE-XIAN LU, HSINCHU (TW)

(21) Appl. No.: 18/603,255

(22) Filed: Mar. 13, 2024

(51) Int. Cl. H10B 20/00

(52) U.S. Cl. CPC H10B 20/387

(57) ABSTRACT

A memory device is provided. The memory device includes a plurality of read only memory (ROM) cells formed in a device layer. Each of the ROM cells includes a gate structure of a transistor coupled to a word line on a front side of the device layer, a first source/drain feature of the transistor coupled to a bit line, and a second source/drain feature of the transistor. The ROM cells include a plurality of first cells corresponding to a first logic value and a plurality of second cells corresponding to a second logic value complementary to the first logic value. In the first cell, the second source/drain feature of the transistor is coupled to a VSS line extending along the same orientation as the bit line. The device layer is formed between the bit line and the VSS line.

### BACKGROUND

Memory devices can be implemented as volatile memory, such as random-access memory (RAM), which requires power to retain stored information, or non-volatile memory, such as read-only memory (ROM), which can retain stored information even when not powered. ROM can be implemented as a programmable read-only memory (PROM), one-time programmable ROM (OTP), erasable programmable read-only memory (EPROM), or electrically erasable programmable read-only memory (EEPROM), for example.

Although existing ROM devices and methods of fabricating the same have generally been adequate for the intended purposes thereof, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a block diagram of an exemplary ROM device, in accordance with some embodiments of the disclosure.

FIG. 2 is a memory array of FIG. 1, in accordance with some embodiments of the disclosure.

FIG. 3 is a cross section of a semiconductor structure of the ROM device, in accordance with some embodiments of the disclosure.

FIG. 4 is a block diagram of memory cells with a ROM code in the memory array of FIG. 2, in accordance with some embodiments of the disclosure.

FIGS. 5A and 5B are top views (or layouts) of a memory array with the units of FIG. 4, in accordance with some embodiments of the disclosure.

FIG. 6 is a perspective view of the unit in the memory array of FIGS. 5A and 5B, in accordance with some embodiments of the present disclosure.

FIGS. 7A and 7B are top views (or layouts) of a memory array with the units of FIG. 4, in accordance with some embodiments of the disclosure.

FIG. 8 is a cross section of the memory array along a line A-A′ in FIGS. 7A and 7B, in accordance with some embodiments of the disclosure.

FIGS. 9A and 9B are top views (or layouts) of a memory array with the units of FIG. 4, in accordance with some embodiments of the disclosure.

FIG. 10 shows a method for manufacturing a semiconductor structure, in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Various semiconductor structures of read-only memory (ROM) in integrated circuits (ICs) are provided in accordance with various exemplary embodiments. Some variations of some embodiments are discussed. Throughout the various views and illustrative embodiments, like reference numbers are used to designate like elements.

According to the embodiments of the present disclosure, read only memory (ROM) devices and methods for manufacturing the ROM devices are provided. The ROM device includes a memory array formed by the memory cells arranged in rows and columns. The memory cells are formed in a device layer, and the bit lines of the memory cells are formed in a front-side interconnection structure over the device layer. A backside interconnection structure under the device layer is used to control ROM code. The backside interconnection structure includes the VSS lines extending along the same orientation as the bit lines. By arranging the bit lines and the VSS lines on opposite sides of the device layer, the number of metal tracks on the front side of the device layer is decreased, thereby alleviating routing complexity and loading of the bit lines, improving balance and performance of signals.

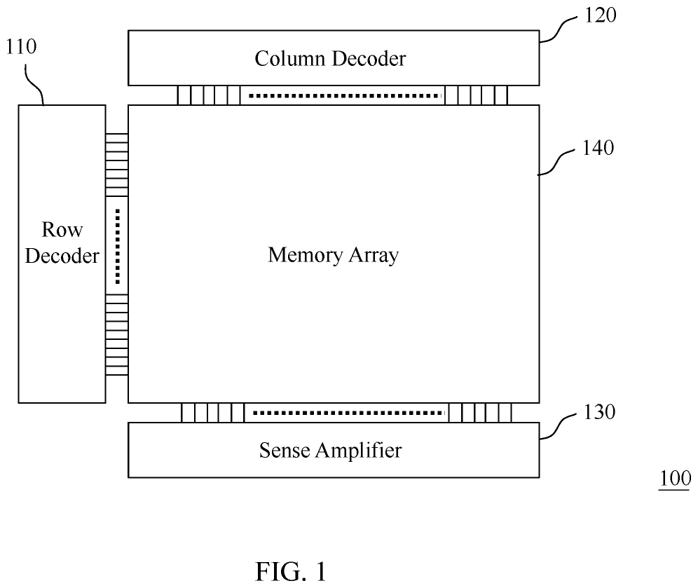

FIG. 1 is a block diagram of an exemplary ROM device 100, in accordance with some embodiments of the disclosure. The ROM device 100 can be programmed (or coded) to store information into one or more memory cells (i.e., the ROM cells). The code or information stored in the ROM device 100 is non-volatile. In some embodiments, the ROM device 100 is implemented in an integrated circuit (IC), and the code or information stored in the ROM device 100, such as instructions for programs and operations, is immediately available when the IC is powered up.

The ROM device 100 includes a row decoder 110, a column decoder 120, a sense amplifier 130, and a memory array 140. According to the address from a controller (not shown), the row decoder 110 is configured to provide the bit lines BL to the memory array 140, and the column decoder 120 is configured to provide the word lines WL to the memory array 140. The memory array 140 includes multiple memory cells arranged in rows and columns of an array, where each memory cell is a ROM cell configured to store one bit of data (i.e., one bit of ROM code). In some embodiments, other arrangements of memory cells are possible without departing from the spirit and scope of the present disclosure. Each memory cell is coupled to the corresponding word line WL and the corresponding bit line BL. The sense amplifier 130 is configured to monitor the bit lines BL to provide output data corresponding to the address form the controller.

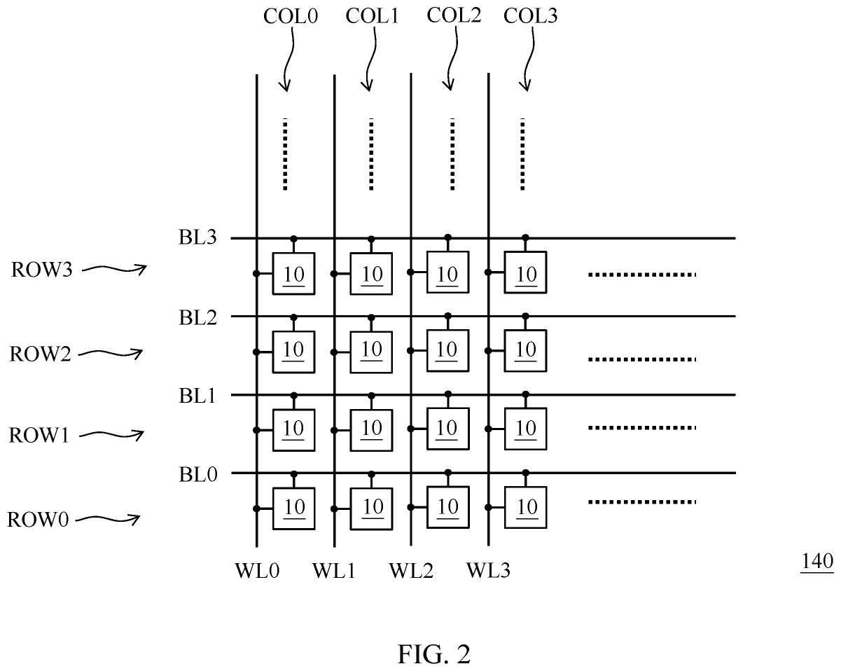

FIG. 2 shows a memory array 140 of FIG. 1, in accordance with some embodiments of the disclosure. The memory array 140 includes multiple memory cells 10 arranged in rows and columns. In the embodiment of FIG. 2, the memory cells 10 of the same row share the same bit line. For example, the memory cells 10 connected to the bit line BL0 are arranged in row ROW0, the memory cells 10 connected to the bit line BL1 are arranged in row ROW1, the memory cells 10 connected to the bit line BL2 are arranged in row ROW2, and so on. Moreover, the memory cells 10 connected to the word line WL0 are arranged in the column COL0, the memory cells 10 connected to the word line WL1 are arranged in the column COL1, and so on.

When the memory array 140 is read in response to the address from the controller (not shown), the bit lines BL corresponding to the address are precharged to a predetermined voltage level (e.g., VDD or a reference voltage). When the memory cells 10 are activated by the word lines WL corresponding to the address, the activated memory cells 10 are coupled to the precharged bit lines BL. If the precharged bit line BL is discharged by the activated memory cell 10, the sense amplifier 130 is configured to provide a first logic value as stored within the activated memory cell 10. If the precharged bit line BL is not discharged by the activated memory cell 10, the sense amplifier 130 is configured to provide a second logic value as being stored within the activated memory cell 10. The second logic value is complementary to the first logic value. For example, when the first logic value is logic “1”, the second logic value is logic “0”. Conversely, when the first logic value is logic “0”, the second logic value is logic “1”.

The memory array 140 is configured to store a ROM code including binary bits. The ROM code is introduced during semiconductor processing by using a ROM code mask during one or more processing steps. In some embodiments, an array of binary codes is represented by the presence or absence of a transistor at a memory cell location. In some embodiments, the presence of the transistor means that the transistor is coupled between a bit line and a ground line (e.g., the VSS line), and the absence of the transistor means that the transistor is floating. The presence or absence of transistors can be achieved through a ROM code mask designed to pattern diffusion, depletion, contacts or metal during various processes.

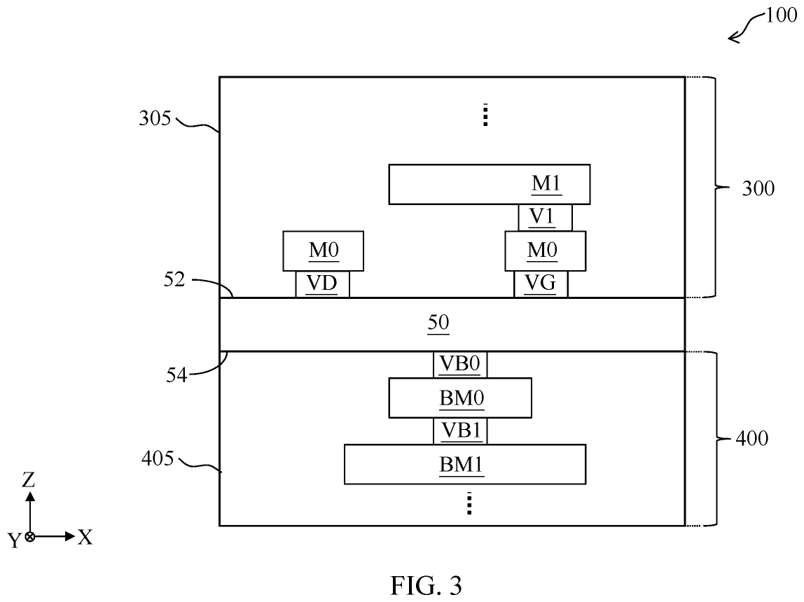

FIG. 3 is a cross section of a semiconductor structure of the ROM device 100, in accordance with some embodiments of the disclosure. The semiconductor structure has a device layer 50 (also referred to as a device region), a front-side interconnect structure 300, and a backside interconnect structure 400. The device layer 50 is where the transistors and main features are located, such as the gate, channel, source/drain region, contact features, and the transistors (e.g., the N-type transistors and the P-type transistors). Source/drain region(s) may refer to a source or a drain, individually or collectively, depending on context. The device layer 50 has a front side 52 and a back side 54.

The front-side interconnect structure 300 is formed over the device layer 50 (e.g., at the front side 52 of the device layer 50), and the backside interconnect structure 400 is formed under the device layer 50 (e.g., at the back side 54 of the device layer 50). The front-side interconnect structure 300 includes an inter-metal dielectric (IMD) 305, the vias VG, VD and V1, and the metal lines M0 and M1. The metal line M0 is formed in the lowest metal layer in the front-side interconnect structure 300, and the lowest metal layer is the metal layer closest to the device layer 50. The backside interconnect structure 400 includes the IMD 405, the vias VB0 and VB1, and the metal lines BM0 and BM1. In the backside interconnect structure 400, the metal line BM0 is formed in the metal layer closest to the device layer 50. The vias and metal lines in the IMD 405 and the IMD 305 are electrically coupled to various transistors and/or components (e.g., the gate, source/drain features, resistors, capacitors, and/or inductors) of the device layer 50, such that the various devices and/or components can operate as specified by design requirements. It should be noted that there may be more vias and metal lines in the IMD 305 and the IMD 405 for connections. The IMD 305 and the IMD 405 may be multilayered.

The backside interconnect structure 400 is at the back side 54 of the device layer 50, and the IMD 405, the vias VB0, VB1, and the metal lines BM0, BM1 may also be referred to as the backside IMD, the backside vias, and the backside metal lines, respectively. Similarly, the front-side interconnect structure 300 is at the front side 52 of the device layer 50, and the IMD 305, the vias VG, VD, V0, and the metal lines M0, M1 may also be referred to as the front-side IMD, the front-side vias, and the front-side metal lines, respectively. In some embodiments, the via VG is connected to the gate structures (gate electrodes) of the transistors, and the via VG is also referred to as the gate via. In some embodiments, the via VD is connected to the source/drain contacts (e.g., source/drain regions) of the transistors.

The formation of the backside interconnect structure 400 may include removing the substrate (if present) in a chemical mechanical polishing (CMP) process, forming a backside dielectric layer (not shown) under the device layer 50, and forming backside contacts or vias (e.g., the via VB0) connected to the source/drain features of the device layer 50. The formation of the front-side interconnect structure 300 is similar to that of the backside interconnect structure 400, the difference being that the formation processes of the front-side interconnect structure 300 are performed at the front side 52 of the device layer 50, and are not described in detail herein.

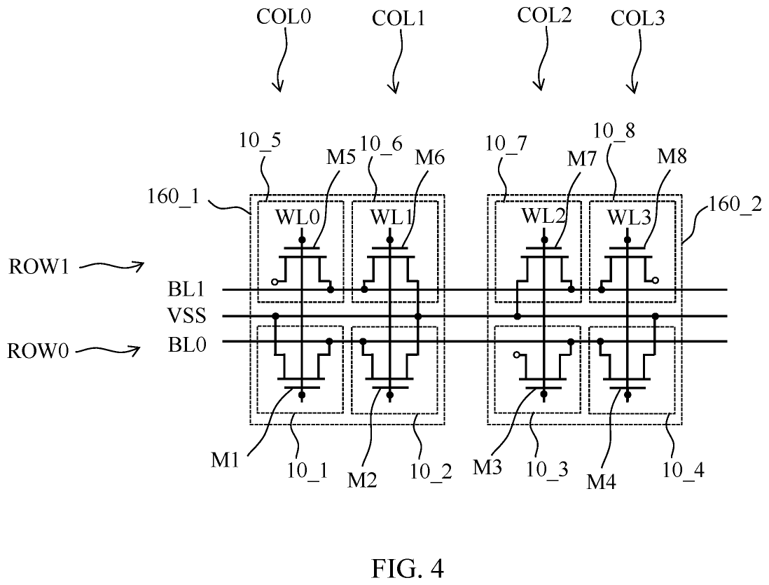

FIG. 4 is a block diagram of memory cells 10_1 through 10_8 with a first ROM code in the memory array 140 of FIG. 2, in accordance with some embodiments of the disclosure. In FIG. 4, each of the memory cells 10_1 through 10_8 includes a transistor. In some embodiments, the transistor is an N-type transistor. In the embodiment of FIG. 4, the memory cells 10_1, 10_2, 10_3 and 10_4 are arranged in the row ROW0 and share the bit line BL0, and the memory cells 10_5, 10_6, 10_7 and 10_8 are arranged in the row ROW1 and share the bit line BL1. Furthermore, the memory cells 10_1 and 10_5 are arranged in the column COL0 and share the word line WL0, the memory cells 10_2 and 10_6 are arranged in the column COL1 and share the word line WL1, the memory cells 10_3 and 10_7 are arranged in the column COL2 and share the word line WL2, and the memory cells 10_4 and 10_8 are arranged in the column COL3 and share the word line WL3. In FIG. 4, the number of memory cells 10_1 through 10_8 is an example and is not intended to limit the disclosure.

In the embodiment of FIG. 4, the memory cells 10_1, 10_2, 10_4, 10_6, and 10_7 are configured to store a first logic value of the first ROM code, and the remaining memory cells are configured to store a second logic value of the first ROM code. In the row ROW0, the transistors M1, M2 and M4 of the memory cells 10_1, 10_2 and 10_4 are coupled between the bit line BL0 and the VSS line, i.e., a first source/drain region of each of the transistors M1, M2 and M4 is coupled to the bit line BL0 and a second source/drain region of each of the transistors M1, M2 and M4 is coupled to the VSS line. In the memory cell 10_3, a first source/drain region of the transistor M3 is coupled to the bit line BL0, and a second source/drain region of the transistor M3 is floating. In the row ROW1, the transistors M6 and M7 of the memory cells 10_6 and 10_7 are coupled between the bit line BL1 and the VSS line. In the memory cells 10_5 and 10_8, a source/drain terminal of the transistor is coupled to the bit line BL1, and another source/drain terminal of the transistor is floating.

Using the bit line BL0 as an example to illustrate reading, the bit line BL0 is precharged by the row decoder 110. When the word line WL0 is controlled (or driven) by the column decoder 120, the transistor M1 of the memory cell 10_1 is turned on, and the precharged bit line BL0 is discharged to the VSS line through the transistor M1, i.e., the bit line BL0 is coupled to the VSS line through the transistor M1. Thus, the stored code of the memory cell 10_1 is sensed by the sense amplifier 130 of FIG. 1 as a first logic value. Similarly, when the word line WL1 is controlled (or driven) by the column decoder 120, the transistor M2 of the memory cell 10_2 is turned on, and the precharged bit line BL0 is discharged to the VSS line through the transistor M2. Thus, the stored code of the memory cell 10_2 is sensed by the sense amplifier 130 as a first logic value.

In the memory cell 10_3, a first source/drain region of the transistor M3 is connected to the bit line BL0 and a second source/drain region of the transistor M3 is floating. When the word line WL2 is controlled (or driven) by the column decoder 120, the transistor M3 is turned on, and precharged bit line BL0 will not be discharged to the VSS line through the transistor M3 because the transistor M3 is not connected between the bit line BL0 and the VSS line. Thus, the stored code of the memory cell 10_3 is sensed by the sense amplifier 130 as a second logic value that is complementary to the first logic value.

In some embodiments, the memory cells 10 of the two adjacent bit lines BL may be divided into multiple units to be implemented in a semiconductor structure of the ROM device 100. For example, the memory cells 10_1 through 10_8 in FIG. 4 are divided into the units 160_1 and 160_2. The unit 160_1 includes the memory cells 10_1, 10_2, 10_5 and 10_6 corresponding to two adjacent word lines WL0 and WL1, and the unit 160_2 includes the memory cells 10_3, 10_4, 10_7 and 10_8 corresponding to two adjacent word lines WL2 and WL3.

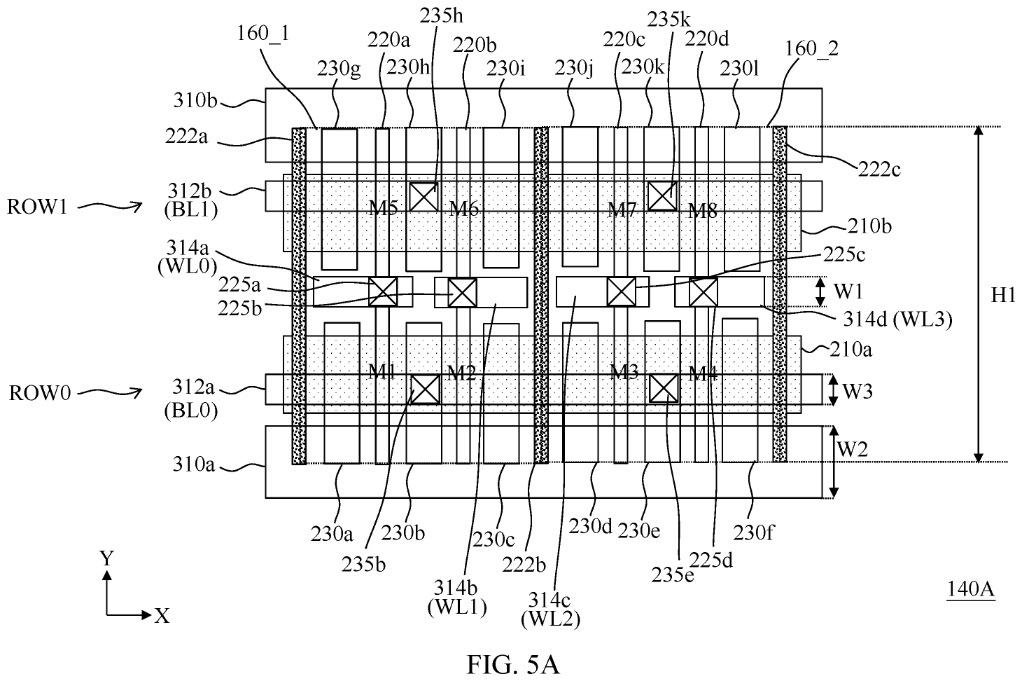

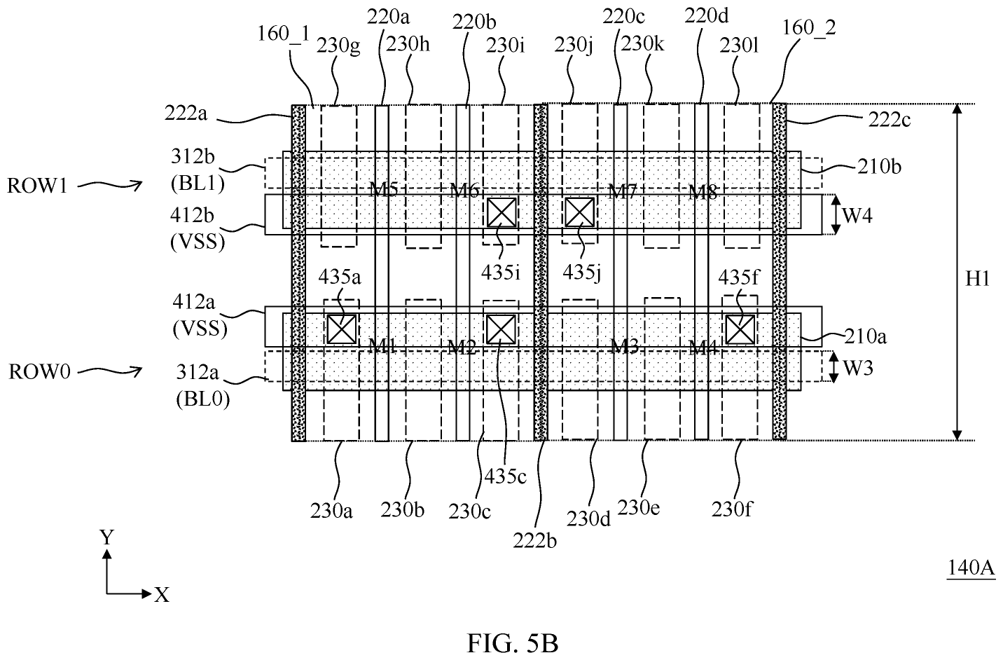

FIG. 5A illustrates an exemplary front-side layout of a memory array 140A with the units 160_1 and 160_2 of FIG. 4, in accordance with some embodiments of the disclosure. In FIG. 5A, the features in the device layer 50 (including transistors) and the front-side interconnect structure 300 (including vias and metal lines) are shown. As described, the unit 160_1 includes the transistors M1, M2, M5 and M6 of the memory cells 10_1, 10_2, 10_5 and 10_6, and the unit 160_2 includes the transistors M3, M4, M7 and M8 of the memory cells 10_3, 10_4, 10_7 and 10_8.

The transistors M1 through M8 are formed in the device layer 50 of FIG. 3. The boundaries of the units 160_1 and 160_2 are defined by dashed lines. The units 160_1 and 160_2 have a unit height H1 along the Y-axis. In some embodiments, the unit height H1 is determined according to the cell height of the memory cells in the units 160_1 and 160_2, and the cell height of the memory cells is related to the width of the active regions 210a and 210b.

In row ROW0 of the memory array 140A, the transistors M1 through M4 are formed in the active region 210a of the device layer 50. In the row ROW1 of the memory array 140A, the transistors M5 through M8 are formed in the active region 210b of the device layer 50. The active regions 210a and 210b extend along the X-axis and have a continuous rectangular shape in the top view. The memory array 140A further includes the gate structures 220a through 220d and the isolation structures 222a through 222c extending along the Y-axis. The gate structures 220a through 220d engage the active region 210a to form the transistors M1 through M4, and the gate structures 220a through 220d engage the active region 210b to form the transistors M5 through M8.

The isolation structures 222a and 222b are arranged in the boundary of the unit 160_1, and the isolation structures 222b and 222c are arranged in the boundary of the unit 160_2. In the memory array 140A, the isolation structures 222a through 222c are dielectric-base dummy gates. In some embodiments, the units in the same row of the memory array 140A are separated from each other by the isolation structures. For example, the units 160_1 and 160_2 are separated from each other by the isolation structure 222b.

In some embodiments, the isolation structures 222a through 222c include the gate material formed by the single dielectric layer or multiple layers and selected from a group consisting of SiO₂, SiOC, SiON, SiOCN, Carbon content oxide, Nitrogen content oxide, Carbon and Nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or a combination thereof. In some embodiments, the isolation structures 222a and 222b may include structures known as continuous poly on diffusion edge (or CPODE), and the CPODE structure may be formed prior to or following a gate replacement process.

The source/drain contacts 230a through 2301 extending along the Y-axis are formed on the source/drain regions (or the source/drain features) of the transistors M1 through M8. The source/drain contact 230b is formed on the common source/drain region of the transistors M1 and M2, and the source/drain contact 230e is formed on the common source/drain region of the transistors M3 and M4. Similarly, the source/drain contact 230h is formed on the common source/drain region of the transistors M5 and M6, and the source/drain contact 230k is formed on the common source/drain region of the transistors M7 and M8.

In FIG. 5A, the metal lines 310a and 310b, the metal lines 312a and 312b and the metal lines 314a through 314d are formed in the lowest metal layer in the front-side interconnect structure 300 of FIG. 3. Moreover, the metal lines 314a through 314d are configured to function as word lines WL0 through WL3, respectively. In order to simplify the description, the upper level connections of the word lines WL0 through WL3 are omitted. The metal lines 314a through 314d extend along the X-axis and have a width W1. The gate structure 220a is connected to the metal line 314a (i.e., the word line WL0) through the connecting feature (e.g., via) 225a. The gate structure 220b is connected to the metal line 314b (i.e., the word line WL1) through the connecting feature 225b. The gate structure 220c is connected to the metal line 314c (i.e., the word line WL2) through the connecting feature 225c. The gate structure 220d is connected to the metal line 314d (i.e., the word line WL3) through the connecting feature 225d. The metal lines 314a through 314c are arranged between the active regions 210a and 210b, i.e., the word lines WL0 through WL3 are disposed between the transistors M1 through M4 of row ROW0 and the transistors M5 through M8 of row ROW1. In other words, the transistors M1 through M4 are separated from the transistors M5 though M8 by the word lines WL0 through WL3.

The metal lines 310a and 310b are arranged on the boundaries of the units 160_1 and 160_2. The metal lines 310a and 310b extend along the X-axis and have a width W2. In some embodiments, the width W2 is greater than the width W1. In some embodiments, the metal lines 310a and 310b are configured to function as the VSS lines for the circuits of the ROM device 100 other than the memory cells 10. In other words, the units 160_1 and 160_2 do not connect to the metal lines 310a and 310b.

In the embodiment of FIG. 5A, the metal lines 312a and 312b are configured to function as the bit lines BL0 and BL1, respectively. In order to simplify the description, the upper level connections of the bit lines BL0 and BL1 are omitted. The metal line 312a is coupled to the source/drain contacts 230b and 230e through the connecting features 235b and 235e, so that a first source/drain region of each of the transistors M1 through M4 is coupled to the bit line BL0. Similarly, the metal line 312b is coupled to the source/drain contacts 230h and 230k through the connecting features 235h and 235k, so that a first source/drain region of each of the transistors M5 through M8 is coupled to the bit line BL1. The metal lines 312a and 312b extend along the X-axis and have a width W3. In some embodiments, the width W3 is equal to the width W1. In some embodiments, the width W3 is less than the width W2, e.g., W3<W2. In FIG. 5A, only the bit lines BL0 and BL1 are formed over the active regions 210a and 210b, thereby decreasing routing complexity and the loading of the bit lines BL0 and BL1.

FIG. 5B illustrates an exemplary backside layout of the memory array 140A with the units 160_1 and 160_2 of FIG. 4, in accordance with some embodiments of the disclosure. In FIG. 5B, the features in the device layer 50 (including transistors) and the backside interconnect structure 400 (including vias and metal lines) are shown. Furthermore, the features in the front-side interconnect structure 300 are shown with dashed lines.

In FIG. 5B, the metal lines 412a and 412b are formed in the same metal layer of the backside interconnect structure 400 of FIG. 3 closest to the device layer 50. The metal lines 412a and 412b are configured to function as the VSS lines. The metal line 412a is coupled to the second source/drain regions (not shown) corresponding to the source/drain contacts 230a, 230c and 230f through the connecting features 435a, 435c and 435f, so that a second source/drain region of each of the transistors M1, M2 and M4 is coupled to the VSS line and a second source/drain region of the transistor M3 is floating, as shown in FIG. 4. Moreover, the metal line 412b is coupled to the second source/drain regions (not shown) corresponding to the source/drain contacts 230i and 230j through the connecting features 435i and 435j, so that a second source/drain region of each of the transistors M6 and M7 is coupled to the VSS line and a second source/drain region of each of the transistors M5 and M8 is floating, as shown in FIG. 4.

The metal lines 412a and 412b extend along the X-axis and have a width W4. In some embodiments, the width W4 is greater than the width W3. In some embodiments, the width W4 is equal to the width W3. In the embodiment of memory array 140A, the metal lines 412a and 412b of the backside interconnect structure 400 non-overlap the metal lines 312a and 312b of the front-side interconnect structure 300 from a top view. Furthermore, the metal lines 412a and 412b are disposed between the metal lines 312a and 312b from a top view. In some embodiments, the metal lines 412a and 412b of the backside interconnect structure 400 partially or completely overlap the metal lines 312a and 312b of the front-side interconnect structure 300 from a top view.

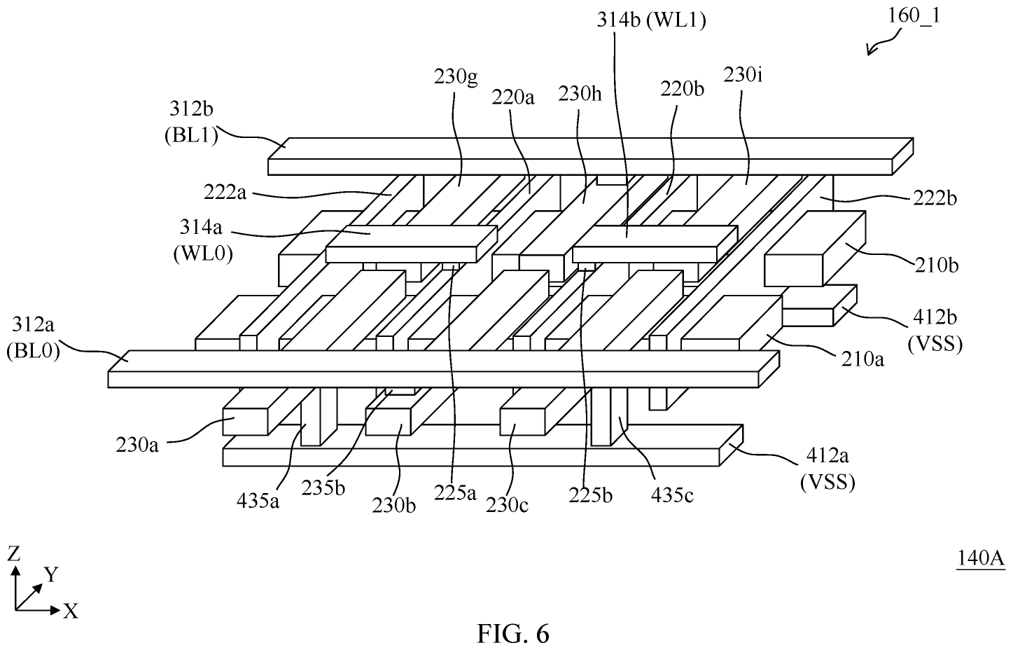

FIG. 6 is a perspective view of the unit 160_1 in the memory array 140A of FIGS. 5A and 5B, in accordance with some embodiments of the present disclosure. As described, the bit lines BL0 and BL1 (e.g., the metal lines 312a and 312b) and the word lines WL0 through WL3 (e.g., the metal lines 314a and 314b) are formed over the active regions 210a and 210b (i.e., the device layer 50), and the VSS lines (e.g., the metal lines 412a and 412b) are formed under the active regions 210a and 210b. In other words, the VSS lines are formed in the backside interconnect structure 400, which may sometimes be referred to as a super power rail (SPR) or a backside power rail (BPR).

In the memory array 140A of FIGS. 5A, 5B and 6, since no VSS line is disposed between the bit lines BL0 and BL1 and the word lines WL0 and WL1, the metal tracks in the lowest metal layer and the upper metal layers over the active regions 210a and 210b are decreased, thereby solving the issue of insufficient layout flexibility. Furthermore, since a spacing between the bit line BL0 (or BL1) and the word lines WL0 and WL1 is increased, the capacitive coupling caused by the parasitic capacitors between the bit line BL0 (or BL1) and the adjacent line in the same metal layer is decreased, thereby decreasing loading of the bit lines BL0 and BL1 and realizing balance of signals and performance optimization. In some embodiments, the bit lines BL0 and BL1 have enough area to become wider, thereby decreasing the parasitic resistance of the bit lines BL0 and BL1. Moreover, when the unit height H1 of the units 160_1 and 160_2 (e.g., the cell height of the memory cells in the 160_1 and 160_2 or the width of the active regions 210a and 210b) is decreased in advanced process, the memory array 140A can avoid the problem of inadequate routing track in the front-side interconnect structure 300.

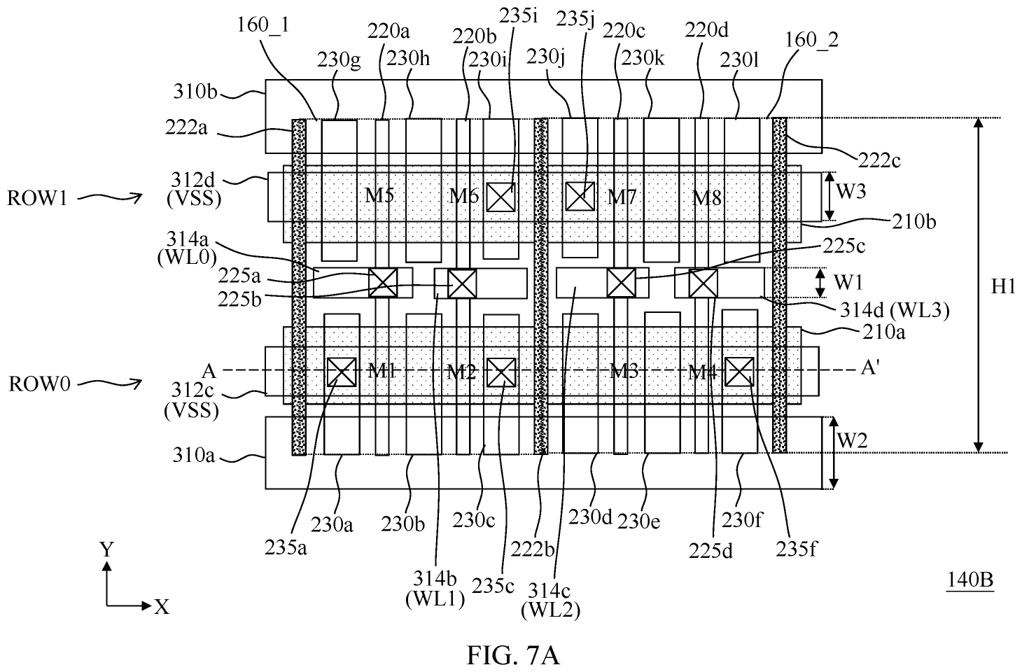

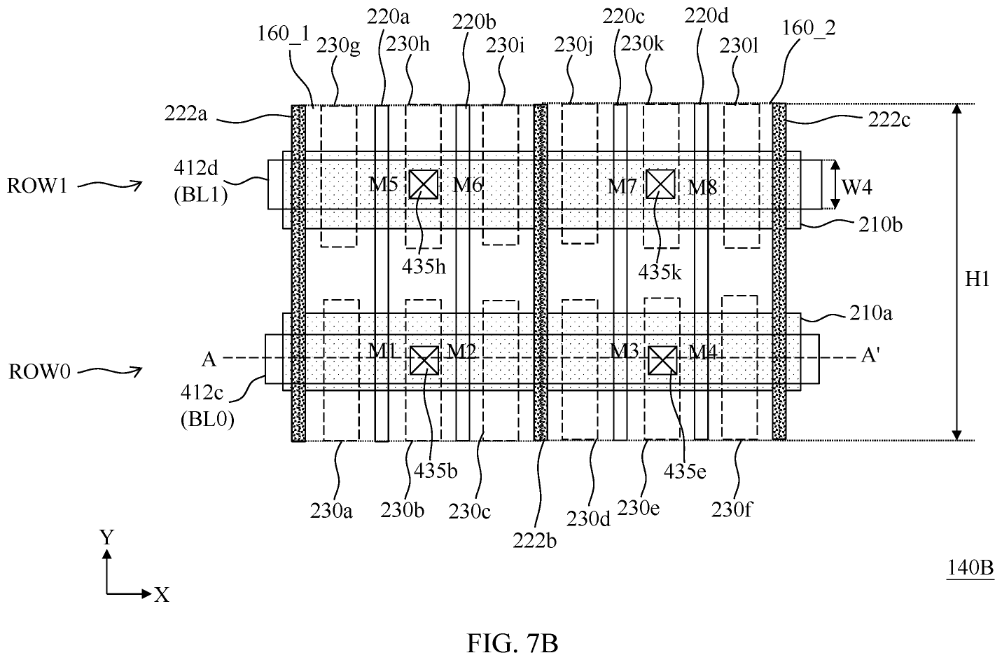

FIGS. 7A and 7B are top views (or layouts) of a memory array 140B with the units 160_1 and 160_2 of FIG. 4, in accordance with some embodiments of the disclosure. FIG. 7A illustrates the features in the device layer 50 (including transistors) and the front-side interconnect structure 300 (including vias and metal lines), and FIG. 7B illustrates the features in the device layer 50 and the backside interconnect structure 400. The configuration of the memory array 140B of FIGS. 7A and 7B is similar to the configuration of the memory array 140A of FIGS. 5A and 5B. The difference between the memory array 140A and the memory array 140B is that the memory array 140B of FIGS. 7A and 7B includes the metal lines 312c and 312d over the active regions 210a and 210b and the metal lines 412c an 412d under the active regions 210a and 210b. Furthermore, the features in the memory array 140B that are the same or similar to those in the memory array 140A are given the same reference numbers, and detailed description thereof is thus omitted.

In FIG. 7A, the metal lines 310a and 310b, the metal lines 312c and 312d and the metal lines 314a through 314d are formed in the lowest metal layer of the front-side interconnect structure 300 of FIG. 3. The metal lines 312c and 312d are configured to function as the VSS line. The metal line 312c is coupled to the source/drain contacts 230a, 230c and 230f through the connecting features 235a, 235c and 235f, so that a second source/drain region of each of the transistors M1, M2 and M4 is coupled to the VSS line and a second source/drain region of the transistor M3 is floating, as shown in FIG. 4. Moreover, the metal line 312d is coupled to the source/drain contacts 230i and 230j through the connecting features 235i and 235j, so that a second source/drain region of each of the transistors M6 and M7 is coupled to the VSS line and a second source/drain region of each of the transistors M5 and M8 is floating, as shown in FIG. 4. The metal lines 312c and 312d extend along the X-axis and have a width W3. In some embodiments, the width W3 is greater than the width W1 and less than the width W2.

In FIG. 7B, the metal lines 412c and 412d are configured to function as the bit lines BL0 and BL1, respectively. The metal line 412c is coupled to the first source/drain regions corresponding to the source/drain contacts 230b and 230e through the connecting features 435b and 435e, so that a first source/drain region of each of the transistors M1 through M4 is coupled to the bit line BL0. Similarly, the metal line 412d is coupled to the first source/drain regions corresponding to the source/drain contacts 230h and 230k through the connecting features 435h and 435k, so that a first source/drain region of each of the transistors M5 through M8 is coupled to the bit line BL1. The metal lines 412c and 412d extend along the X-axis and have a width W4. In some embodiments, the width W4 of the metal lines 412c and 412d is equal to the width W3 of the metal lines 312c and 312d of FIG. 7A. In some embodiment, the width W4 is greater than the width W3. In some embodiments, the metal lines 412c and 412d shown in FIG. 7B may partially or completely overlap the metal lines 312c and 312d shown in FIG. 7A from a top view.

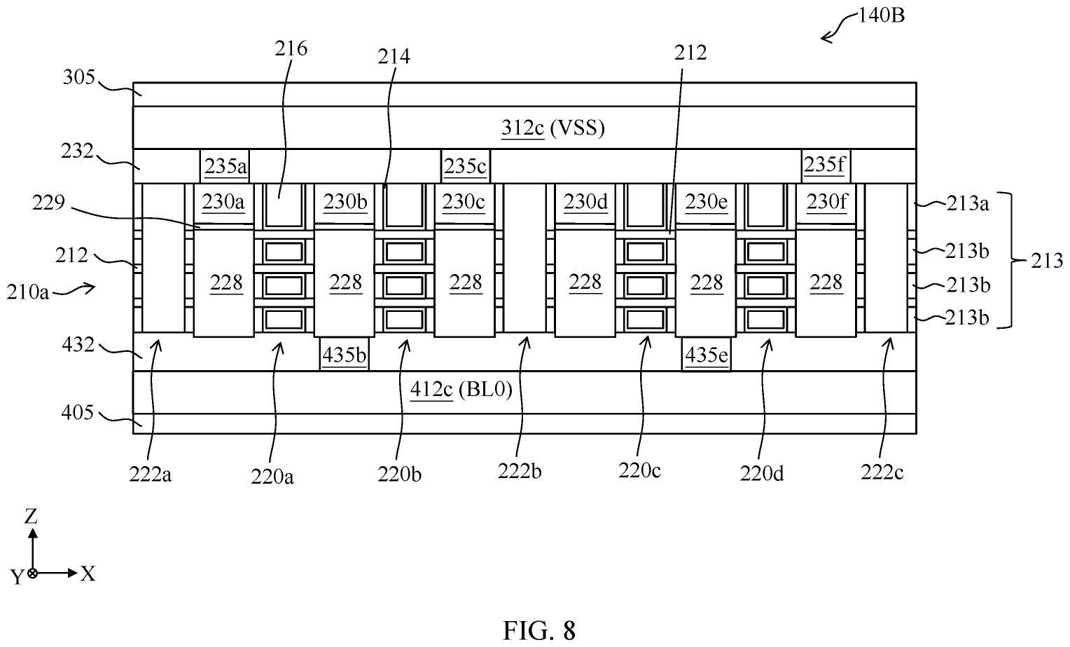

FIG. 8 is a cross section of the memory array 140B along a line A-A′ in FIGS. 7A and 7B, in accordance with some embodiments of the disclosure. In some embodiments, the active region 210a constructed by the nanostructures 212 and the source/drain features 228 remains continuity. More specifically, the nanostructures 212 of the gate structures 220a through 220d, the source/drain features 228, and the nanostructures 212 of the isolation structures 222a through 222c are connected with each other to construct the continuous active region 210a.

In FIG. 8, the source/drain contacts 230a through 230f, the connecting features 235a, 235c, and 235f, and the metal line 312c of the front-side interconnect structure 300 are formed over the active region 210a. Furthermore, the connecting features 435b and 435e and the metal line 412b of the backside interconnect structure 400 are formed under the active region 210a.

Each of gate structures 220a through 220d and each of isolation structures 222a through 222c includes the nanostructures 212 extending along an X-axis and vertically arranged (or stacked) along a Z-axis. More specifically, the nanostructures 212 are spaced from each other along the Z-axis. In some embodiments, the nanostructures 212 may also be referred to as channels, channel layers, nanosheets, or nanowires. The nanostructures 212 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 212 include silicon for N-type gate-all-around (GAA) field effect transistors (FETs). In some embodiments, the nanostructures 212 are all made of silicon, and the type of GAA transistors depend on work function metal layer wrapping around the nanostructures 212.

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The gate dielectric layer 214 wraps around the nanostructures 212, and the gate electrode 216 wraps around the gate dielectric layer 214. The gate electrode 216 may include polysilicon or work function metal. The work function metal includes TiN, TaN, TiAl, TiAlN, TaAl, TaAIN, TaAIC, TaCN, WNC, Co, Ni, Pt, W, combinations thereof, or other suitable material. The gate dielectric layer 214 may include dielectric materials, such as silicon oxide, silicon nitride, silicon oxynitride, dielectric material(s) with high dielectric constant (high-k), or a combination thereof. Examples of high-k dielectric materials include TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material.

The spacers 213 are on sidewalls of the gate structures 220a through 220d and the isolation structures 222a through 222c. The spacers 213 include the outer spacers 213a and the inner spacers 213b. The outer spacers 213a are over the nanostructures 212 and on top sidewalls of the gate structures 220a through 220d and the isolation structures 222a through 222c. The outer spacers 213a may include multiple dielectric materials and be selected from a group consist of SiO₂, Si₃N₄, carbon doped oxide, nitrogen doped oxide, porous oxide, air gap, or, or a combination thereof. The inner spacers 213b are between the nanostructures 212. In some embodiments, the inner spacers 213b may include a dielectric material having higher K value (dielectric constant) than the outer spacers 213a and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

Each source/drain feature 228 is disposed between two adjacent gate structures and connect (or contact) the nanostructures 212 of the transistors. Each source/drain feature 228 is shared by two adjacent gate structures. In some embodiments, the shared source/drain feature 228 may be also referred to as the common source/drain feature (or common source/drain region) of two adjacent transistors. The source/drain features 228 are formed by the epitaxially-grown materials. In some embodiments, for the N-type transistors in the memory array 140B, the epitaxially-grown materials may include SiP, SiC, SiPC, SiAs, Si, or a combination thereof.

The source/drain contacts 230a through 230f extending along the Y-axis are over and contact (or connect) the source/drain features 228. Furthermore, the silicide features 229 is formed between the source/drain contacts 230a through 230f and the source/drain features 228. The silicide features 229 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

Above the active region 210a, the connecting features 235a, 235c and 235f are formed in the inter-layer dielectric (ILD) 232 and over and contact the source/drain contacts 230a, 230c and 230f, respectively. Furthermore, the metal line 312c is formed over and contact the connecting features 235a, 235c and 235f. Therefore, the source/drain contacts 230a, 230c and 230f are electrically connected through the connecting features 235a, 235c and 235f and the metal line 312c. Below the active region 210a, the connecting features 435b and 435e are formed in the dielectric 432 and under and contact the source/drain features 228 corresponding to the source/drain contacts 230b and 230e, respectively. Therefore, the source/drain contacts 230b and 230e are electrically connected through the connecting features 435b and 435e and the metal line 412c. In some embodiments, the silicide features (not shown) are formed between the connecting features 435b and 435e and the source/drain features 228.

The IMD 305, the IMD 405, the ILD 232 and the dielectric 432 may include one or more dielectric layers including dielectric materials, such as tetraethylortho silicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the source/drain contacts, the connecting features and the metal lines in the memory array 140B are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

By arranging the bit line BL0 and the VSS line on opposite sides of the active region 210a, the routing loading over the active region 210a (e.g., in the front-side interconnection structure 300) is decreased, thereby improving circuit density for the memory array 140B. The fewer metal lines in the same area (layer) also benefits the metal conductor resistance-capacitance (RC) performance (can be set for either Lower Resistance (wider width) or lower capacitance (larger space), or both), so as to decrease the RC delay and power IR drop for the bit line BL0.

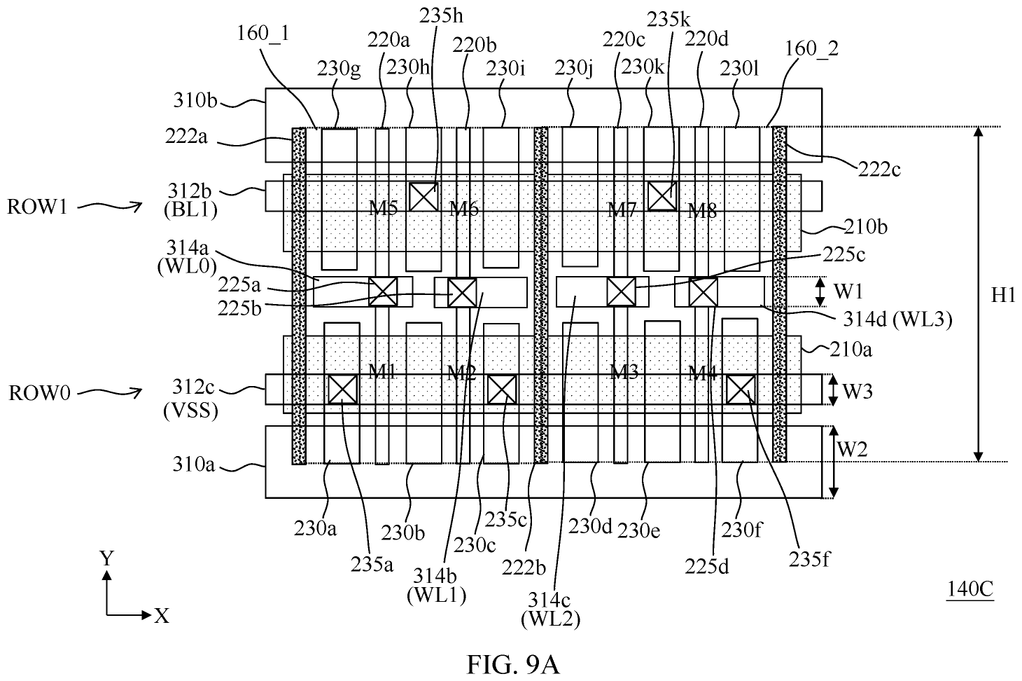

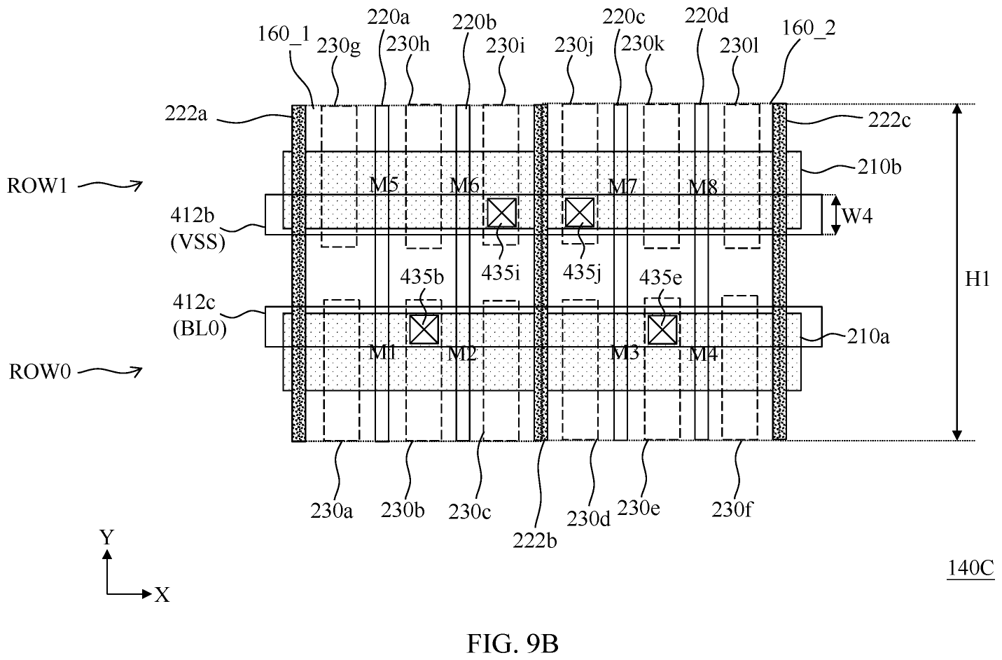

FIGS. 9A and 9B are top views (or layouts) of a memory array 140C with the units 160_1 and 160_2 of FIG. 4, in accordance with some embodiments of the disclosure. FIG. 9A illustrates the features in the device layer 50 (including transistors) and the front-side interconnect structure 300 (including vias and metal lines), and FIG. 9B illustrates the features in the device layer 50 and the backside interconnect structure 400. The configuration of the memory array 140C of FIGS. 9A and 9B is similar to the configuration of the memory array 140A of FIGS. 5A and 5B. The difference between the memory array 140A and the memory array 140C is that the memory array 140C of FIGS. 9A and 9B includes the metal line 312c over the active region 210a and the metal line 412c under the active region 210a. Furthermore, the features in the memory array 140C that are the same or similar to those in the memory array 140A are given the same reference numbers, and detailed description thereof is thus omitted.

In FIG. 9A, the metal lines 310a and 310b, the metal lines 312b and 312c and the metal lines 314a through 314d are formed in the lowest metal layer of the front-side interconnect structure 300 of FIG. 3. The metal line 312c is configured to function as the VSS line. The metal line 312c is coupled to the source/drain contacts 230a, 230c and 230f through the connecting features 235a, 235c and 235f, so that a second source/drain region of each of the transistors M1, M2 and M4 is coupled to the VSS line and a second source/drain region of the transistor M3 is floating, as shown in FIG. 4. Moreover, the metal line 312b is configured to function as the bit line BL1. The metal line 312b is coupled to the source/drain contacts 230h and 230k through the connecting features 235h and 235k, so that a first source/drain region of each of the transistors M5 through M8 is coupled to the bit line BL1. The metal lines 312b and 312c have the same width W3.

In FIG. 9B, the metal line 412c is configured to function as the bit line BL0. The metal line 412c is coupled to the first source/drain regions (not shown) corresponding to the source/drain contacts 230b and 230e through the connecting features 435b and 435e, so that a first source/drain region of each of the transistors M1 through M4 is coupled to the bit line BL0. Furthermore, the metal line 412b is configured to function as the VSS line. The metal line 412b is coupled to the second source/drain regions (not shown) corresponding to the source/drain contacts 230i and 230j through the connecting features 435i and 435j, so that a second source/drain region of each of the transistors M6 and M7 is coupled to the VSS line and a second source/drain region of each of the transistors M5 and M8 is floating, as shown in FIG. 4. The metal lines 412b and 412c have the same width W4. In some embodiments, the metal lines 412c and 412b shown in FIG. 9B may partially or completely overlap the metal lines 312c and 312b shown in FIG. 9A from a top view.

In the memory array 140C of FIGS. 9A and 9B, the bit lines and VSS lines are arranged alternately in the front-side interconnect structure 300 and the backside interconnect structure 400 and correspond to individual rows of the memory array 140C. For example, in some embodiments, the VSS line (e.g., the metal line 312c) is arranged corresponding to the row ROW0, the bit line BL1 (e.g., the metal line 312b) is arranged corresponding to the ROW1, the VSS line (not shown) is arranged corresponding to the row ROW2 (not shown), the bit line BL3 (not shown) is arranged corresponding to the row ROW3 (not shown), and so on. Therefore, the bit lines BL1 and BL3 and the VSS lines are arranged alternately in the front-side interconnect structure 300. Similarly, in some embodiments, the bit line BL0 (e.g., the metal line 412c) is arranged corresponding to the ROW0, the VSS line (e.g., the metal line 412b) is arranged corresponding to the row ROW1, the bit line BL2 (not shown) is arranged corresponding to the row ROW2 (not shown), the VSS line (not shown) is arranged corresponding to the row ROW3 (not shown), and so on. Therefore, the bit lines BL0 and BL2 and the VSS lines are arranged alternately in the backside interconnect structure 400. In other words, two adjacent rows respectively correspond to the bit line and the VSS line in the same interconnection structure. Furthermore, the bit lines of two adjacent rows are respectively arranged in the front-side interconnection structure 300 and the backside interconnection structure 400. For example, the bit line BL0 of the row ROW0 is arranged in the backside interconnection structure 400, and the bit line BL1 of the row ROW1 is arranged in the front-side interconnection structure 300.

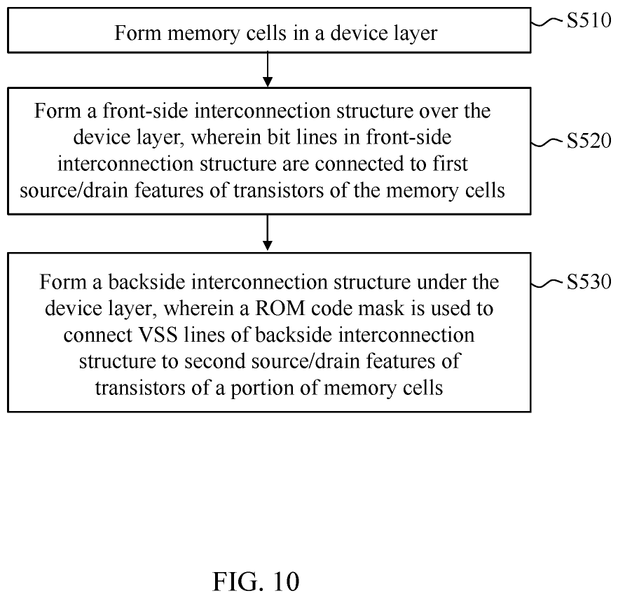

FIG. 10 shows a method for manufacturing a semiconductor structure, in accordance with some embodiments of the disclosure, and the semiconductor structure includes the ROM device 100 of the embodiments. It should be understood that the embodiment method shown in FIG. 10 is merely an example of many possible embodiments. One of ordinary skill in the art could recognize many variations, alternatives, and modifications. For example, various steps as illustrated in FIG. 10 may be added, removed, replaced, rearranged, or repeated.

In operation S510, the memory cells in the memory array are formed in a device layer, and each memory cell includes a transistor. In operation S520, a front-side interconnect structure is formed at a front side of the device layer. In the front-side interconnect structure, the bit lines of the memory array are connected to first source/drain regions of the transistors of the memory cells. In operation S530, a backside interconnect structure is formed at a back side of the device layer. When forming the backside interconnect structure, a ROM code mask is used to connect the VSS lines to second source/drain regions of the transistors of a portion of memory cells (e.g., the memory cells corresponding to a specific logic value of the ROM code). The memory cell having the transistor connected to the VSS line is configured to store a first logic value of the ROM code, and the memory cell having the transistor not connected to the VSS line is configured to store a second logic value of the ROM code. As described, the second logic value is complementary to the first logic value.

In some embodiments, the first source/drain regions of the transistors of the memory cells are configured to connect the bit lines of the backside interconnect structure, and the second source/drain regions of the transistors of the portion of memory cells are configured to connect the VSS lines of the front-side interconnect structure.

In some embodiments, the first source/drain regions of the transistors of the memory cells in specific rows (e.g., odd rows or even rows) are configured to connect the bit lines of the backside interconnect structure, and the first source/drain regions of the transistors of the memory cells in the remaining rows are configured to connect the bit lines of the front-side interconnect structure. Furthermore, according to the ROM code, the second source/drain regions of the transistors of a portion of memory cells in the specific rows are configured to connect the VSS lines of the front-side interconnect structure, and the second source/drain regions of the transistors of a portion of memory cells in the remaining rows are configured to connect the VSS lines of the backside interconnect structure.

According to some embodiments, a memory device is provided. The memory device includes a plurality of read only memory (ROM) cells formed in a device layer, each including a gate structure of a transistor coupled to a word line on a front side of the device layer, a first source/drain feature of the transistor coupled to a bit line, and a second source/drain feature of the transistor. The ROM cells include a plurality of first cells corresponding to a first logic value and a plurality of second cells corresponding to a second logic value that is complementary to the first logic value. In the first cell, the second source/drain feature of the transistor is coupled to a VSS line extending along the same orientation as the bit line. The device layer is formed between the bit line and the VSS line.

According to some embodiments, a memory device is provided. The device memory includes a device layer, a first interconnect structure formed on a front side of the device layer, a second interconnect structure formed on a backside of the device layer, and a memory array formed in the device layer. The memory array includes a plurality of read only memory (ROM) cells. The ROM cells in a first row of the memory array share a first bit line of the first interconnect structure, and the ROM cells in a second row of the memory array share a second bit line of the second interconnect structure. In the first row of the memory array, the ROM cells corresponding to a first logic value are coupled to a first VSS line of the second interconnect structure, and in the second row of the memory array, the ROM cells corresponding to the first logic value are coupled to a second VSS line of the first interconnect structure. The first bit line, the second bit line, the first VSS line and the second VSS line extend along the same orientation.

According to some embodiments, a method for manufacturing a memory device is provided, in which a memory array is formed in a device layer. The memory array includes a plurality of memory cells arranged in a plurality of rows and a plurality of columns, and each of the memory cells includes a transistor. A first interconnection structure is formed on a front side of the device layer. The first interconnection structure includes a plurality of bit lines, and each of the bit lines is coupled to first source/drain regions of the transistors of the memory cells in the same row of the memory array. A read only memory (ROM) code mask corresponding to a ROM code is used to form a second interconnection structure on a back side of the device layer. A plurality of VSS lines of the second interconnection structure are connected to second source/drain regions of the transistors of the memory cells corresponding to a first logic value of the ROM code.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of read only memory (ROM) cells formed in a device layer, and each of the ROM cells comprises:
a gate structure of a transistor coupled to a word line on a front side of the device layer;
a first source/drain feature of the transistor coupled to a bit line; and
a second source/drain feature of the transistor,
wherein the ROM cells comprise a plurality of first cells corresponding to a first logic value and a plurality of second cells corresponding to a second logic value that is complementary to the first logic value,
wherein in the first cell, the second source/drain feature of the transistor is coupled to a VSS line extending along the same orientation as the bit line,
wherein the device layer is formed between the bit line and the VSS line.

2. The memory device of claim 1, wherein one of the bit line and the VSS line is disposed on the front side of the device layer, and the other one of the bit line and the VSS line is disposed on a backside of the device layer.

3. The memory device of claim 1, wherein the bit line or the VSS line disposed on the front side of the device layer has the same width as the word line.

4. The memory device of claim 1, wherein the bit line or the VSS line disposed on a backside of the device layer has a wider width than the word line.

5. The memory device of claim 1, wherein in the second cell, the second source/drain feature of the transistor is floating.

6. The memory device of claim 1, wherein in the first cell, the bit line overlaps the VSS line from a top view.

7. The memory device of claim 1, wherein in the first cell, the bit line non-overlaps the VSS line, and the VSS line is disposed between the bit line and the word line from a top view.

8. A memory device, comprising:
a device layer;
a first interconnect structure formed on a front side of the device layer;
a second interconnect structure formed on a backside of the device layer; and
a memory array formed in the device layer, and comprising a plurality of read only memory (ROM) cells,
wherein the ROM cells in a first row of the memory array share a first bit line of the first interconnect structure, and the ROM cells in a second row of the memory array share a second bit line of the second interconnect structure,
wherein in the first row of the memory array, the ROM cells corresponding to a first logic value are coupled to a first VSS line of the second interconnect structure, and in the second row of the memory array, the ROM cells corresponding to the first logic value are coupled to a second VSS line of the first interconnect structure,
wherein the first bit line, the second bit line, the first VSS line and the second VSS line extend along the same orientation.

9. The memory device of claim 8, wherein the first bit line and the second VSS line have a first width in the first interconnect structure, and the second bit line and the first VSS line have a second width in the second interconnect structure, wherein the second width is greater than or equal to the first width.

10. The memory device of claim 8, wherein the first bit line and the second VSS line are formed in the same metal layer of the first interconnect structure, and the second bit line and the first VSS line are formed in the same metal layer of the second interconnect structure.

11. The memory device of claim 8, wherein the first bit line overlaps the first VSS line and the second bit line overlaps the second VSS line from a top view.

12. The memory device of claim 8, wherein the first bit line non-overlaps the first VSS line, and the second bit line non-overlaps the second VSS line from a top view.

13. The memory device of claim 8, wherein each of the ROM cells comprises:
a gate structure of a transistor coupled to a word line of the first interconnect structure;
a first source/drain feature of the transistor; and
a second source/drain feature of the transistor,
wherein in each of the ROM cells of the first row of the memory array, the first source/drain feature of the transistor is connected to the first bit line, and in each of the ROM cells of the second row of the memory array, the first source/drain feature of the transistor is connected to the second bit line.

14. The memory device of claim 13, wherein in the first row of the memory array, the second source/drain feature of the transistor in the ROM cell corresponding to the first logic value is coupled to the first VSS line, and the second source/drain feature of the transistor in the ROM cell corresponding to a second logic value is floating.

15. The memory device of claim 14, wherein in the second row of the memory array, the second source/drain feature of the transistor in the ROM cell corresponding to the first logic value is coupled to the second VSS line, and the second source/drain feature of the transistor in the ROM cell corresponding to the second logic value is floating.

16. A method for manufacturing a memory device, comprising:
forming a memory array in a device layer, wherein the memory array comprises a plurality of memory cells arranged in a plurality of rows and a plurality of columns, and each of the memory cells comprises a transistor;
forming a first interconnection structure on a front side of the device layer, wherein the first interconnection structure comprises a plurality of bit lines, and each of the bit lines is coupled to first source/drain regions of the transistors of the memory cells in the same row of the memory array; and
using a read only memory (ROM) code mask corresponding to a ROM code to form a second interconnection structure on a back side of the device layer,
wherein a plurality of VSS lines of the second interconnection structure are connected to second source/drain regions of the transistors of the memory cells corresponding to a first logic value of the ROM code.

17. The method of claim 16, wherein forming the memory array in the device layer further comprises:
forming the transistors of the memory cells of the same row in the same active region extending along the same orientation as the bit lines and the VSS lines,
wherein each of the transistors of the memory cells of the same row has a gate structure connected to a respective word line of the first interconnection structure.

18. The method of claim 16, wherein in the memory cells corresponding to a second logic value of the ROM code, the second source/drain regions of the transistors are floating, and the second logic value is complementary to the first logic value.

19. The method of claim 16, wherein the bit lines of the first interconnection structure overlap the VSS lines of the second interconnection structure from a top view.

20. The method of claim 16, wherein the bit lines of the first interconnection structure non-overlap the VSS lines of the second interconnection structure from a top view.
